(19) United States
(12) Patent Application Publication
(10) Pub. No.: US 2006/0284272 A1
(43) Pub. Date: Dec. 21, 2006

(54) Gate structure and method for preparing the same

(75) Inventor: Heng Kai Hsu, Hsinchu City (TW)

Correspondence Address: OLIFF & BERRIDGE, PLC, P.O. BOX 19928, ALEXANDRIA, VA, 22320, US

(73) Assignee: PROMOS TECHNOLOGIES, INC., Hsinchu (TW)

(21) Appl. No.: 11/181,943

(22) Filed: Jul. 15, 2005

(30) Foreign Application Priority Data
Jun. 15, 2005 (TW) 094119801

(51) Int. Cl. H01L 29/94; H01L 21/3205

(52) U.S. Cl. 257/412; 257/413; 438/585; 257/E29.128

(57) ABSTRACT

The present gate structure comprises a gate oxide layer positioned on a substrate, a conductive stack positioned on the gate oxide layer, a passivation layer positioned on the sidewall of the conductive stack, and a cap layer positioned on the conductive stack. The conductive stack includes a polysilicon layer, a tungsten nitride layer, and a tungsten layer. The passivation layer can be made of silicon oxide, silicon nitride, or silicon oxynitride. The present method for preparing the gate structure comprises steps of forming a gate oxide layer, a conductive stack, and a cap layer on a semiconductor substrate in sequence, removing a portion of the gate oxide layer, the conductive stack, and the cap layer to form at least one opening, implanting silicon ions into the sidewall of the conductive stack, and performing a thermal treating process to transform the sidewall with silicon ions into a passivation layer.

### BACKGROUND OF THE INVENTION

(A) Field of the Invention

The present invention relates to a gate structure and method for preparing the same, and more particularly, to a gate structure including a passivation layer on the sidewall and method for preparing the same, which can prevent the conductive layer of the gate structure from being corroded by the oxidant.

(B) Description of the Related Art

As semiconductor fabrication technology shrinks into nanometer scale, the line width and the pitch between semiconductor devices shrink correspondingly, which results in an increase of the resistance of conductive wire and an increase of the capacitance between the conductive wires, and the RC-delay effect emerges. The RC-delay causes several negative influences such as a decrease in signal propagation speed, an increase in cross talk noise, and an increase in power consumption, of which the decrease in signal propagation speed is the most serious. In order to reduce the RC-delay effect, researchers use tungsten (W) with a lower resistance to prepare the gate structure of the MOS transistor.

FIG. 1 to FIG. 3 illustrate a method for preparing a gate structure 10 according to the prior art. A gate oxide layer 14, a polysilicon layer 16, a tungsten nitride layer 18, a tungsten layer 20, and a silicon nitride layer 22 are formed on a semiconductor substrate 12 in sequence. The lithographic process and the etching process are then used to remove a portion of the gate oxide layer 14, the polysilicon layer 16, the tungsten nitride layer 18, the tungsten layer 20, and the silicon nitride layer 22 to form the gate structure 10, as shown in FIG. 2.

After the gate structure is completed, the ion implanting process is performed to form diffusion regions 24 in the semiconductor substrate 12, and a series of cleaning processes are performed to remove contaminants such as organics, micro particles, and heavy metals from the surface of the semiconductor substrate 12 to prevent the electrical properties of the gate structure 10 and quality control of the semiconductor fabrication process from being influenced by the contaminant. At present, the cleaning solution including hydrogen peroxide and sulfuric acid is most widely used to remove the contaminant from the surface of the semiconductor substrate 10.

Referring to FIG. 3, the hydrogen peroxide of the cleaning solution is a strong oxidant, which is likely to corrode the sidewall of the tungsten layer 20 to form concaves on the sidewall of the gate structure 10. As a result, the corrosion of the hydrogen peroxide on the tungsten layer 20 leads to the decrease of the cross-sectional area of the tungsten layer 20, i.e., increases the resistance of the gate structure 10. Particularly, the hydrogen peroxide may even corrode the tungsten layer 20 completely, which will result in a broken conductive wire.

### SUMMARY OF THE INVENTION

According to one embodiment of the present invention, the gate structure comprises a gate oxide layer positioned on a semiconductor substrate, a conductive stack positioned on the gate oxide layer, a passivation layer positioned on the sidewall of the conductive stack, and a cap layer positioned on the conductive stack. The conductive stack includes a polysilicon layer positioned on the gate oxide layer, a tungsten nitride layer positioned on the polysilicon layer, and a tungsten layer positioned on the tungsten nitride layer. The passivation layer can be made of silicon oxide, silicon nitride, or silicon oxynitride.

According to one embodiment of the present invention, the method for preparing the gate structure comprises steps of forming a gate oxide layer, a conductive stack, and a cap layer on a semiconductor substrate in sequence, removing a portion of the gate oxide layer, the conductive stack, and the cap layer to form at least one opening, performing an ion implanting process such as a tile implanting process to implant silicon ions into the sidewall of the conductive stack, and performing a thermal treating process to transform the sidewall with silicon ions into a passivation layer.

The prior art method exposes the tungsten layer of the gate structure to the oxidant in a cleaning solution, and the tungsten layer is corroded. On the contrary, the present gate structure includes a passivation layer on the sidewall, and the passivation layer can protect the tungsten layer from exposure to the oxidant in the cleaning solution. Consequently, the present invention can prevent the conductive stack from being corroded by the oxidant to maintain the profile and the electrical properties of the gate structure.

### BRIEF DESCRIPTION OF THE DRAWINGS

The objectives and advantages of the present invention will become apparent upon reading the following description and upon reference to the accompanying drawings in which:

FIG. 1 to FIG. 3 illustrate a method for preparing a gate structure according to the prior art; and

FIG. 4 to FIG. 8 illustrate a method for preparing a gate structure according to one embodiment of the present invention.

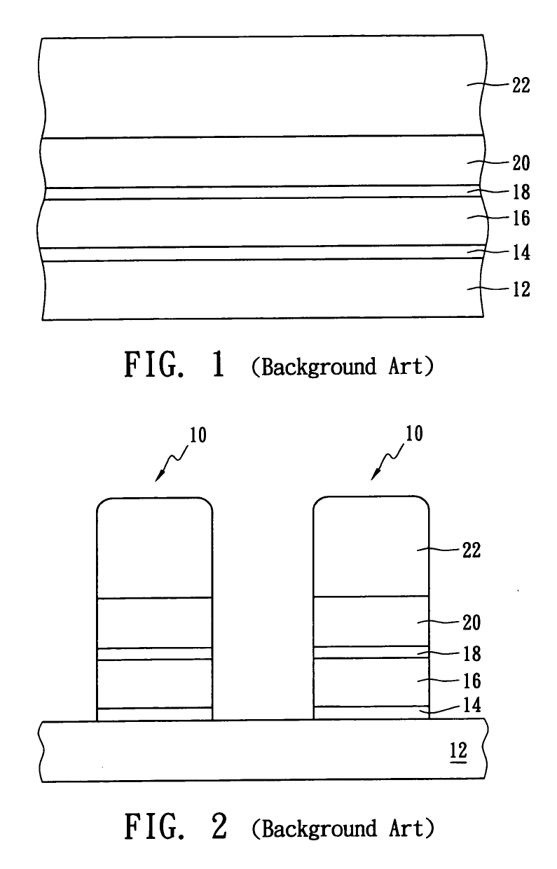

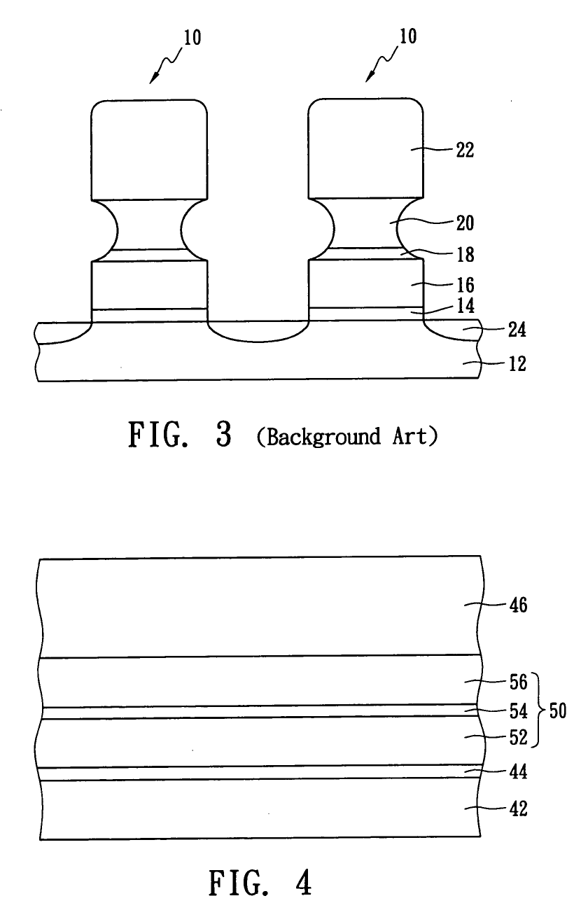

### DETAILED DESCRIPTION OF THE INVENTION

FIG. 4 to FIG. 8 illustrate a method for preparing a gate structure 40 according to one embodiment of the present invention. A gate oxide layer 44, a conductive stack 50, and a cap layer 46 are formed on a semiconductor substrate 42 in sequence, wherein the conductive stack 50 includes a polysilicon layer 52 positioned on the gate oxide layer 44, a tungsten nitride layer 54 positioned on the polysilicon layer 52, and a tungsten layer 56 positioned on the tungsten nitride layer 54, as shown in FIG. 4.

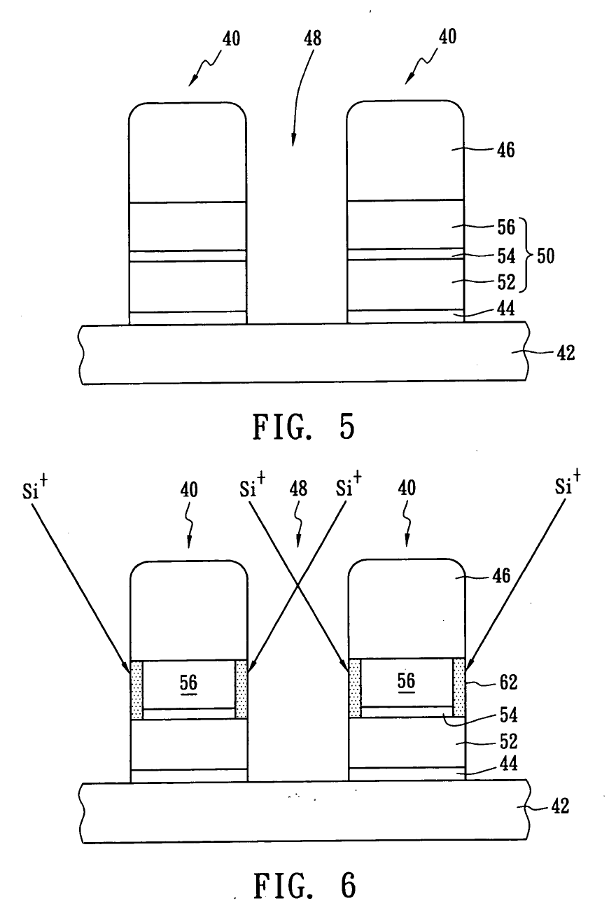

Referring to FIG. 5, the lithographic process and the etching process are used to remove a predetermined portion of the gate oxide layer 44, the conductive stack 50, and the cap layer 46 to form at least one opening 48. Subsequently, an implanting process such as the tilt implanting process is performed to implant silicon ions into the sidewall of the conductive stack 50 through the opening 48, wherein implanting silicon ions into the tungsten layer 56 and the tungsten nitride layer 54 will form a doped region on the sidewalls of the tungsten layer 56 and the tungsten nitride layer 54. The semiconductor substrate 42 is heated in an atmosphere including at least one inert gas up to 800° C. to perform an annealing process to transform the doped region into to a tungsten silicide layer 62, as shown in FIG. 6.

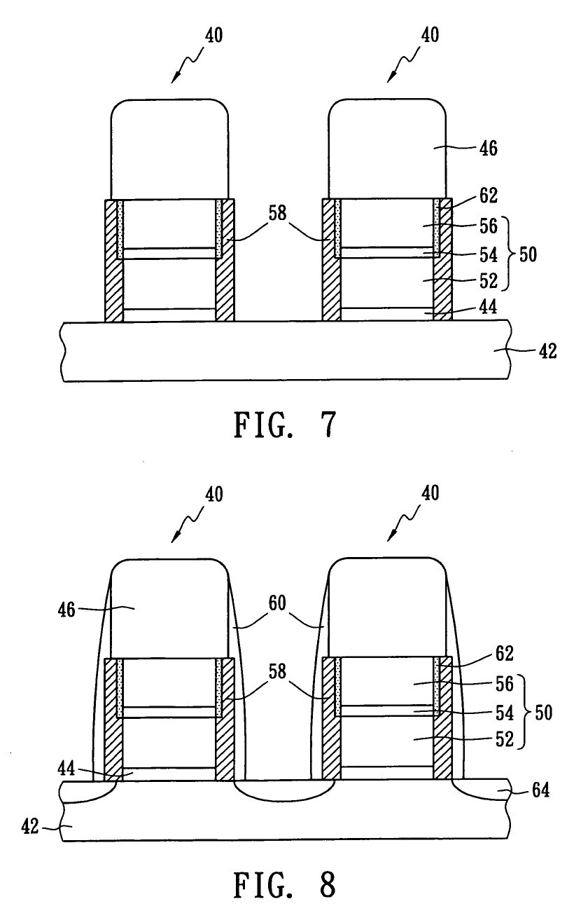

Referring to FIG. 7, a thermal treating process such as a selective oxidation process is performed by placing the semiconductor substrate 42 in an atmosphere including hydrogen (90%) and steam (10%) at a temperature between 900° C. and 1200° C. to transform silicon ions in a predetermined portion of the sidewall, i.e., a portion of the sidewall of the tungsten silicide layer 62, into silicon oxide to form a passivation layer 58 on the sidewall of the conductive stack 50. Particularly, the selective oxidation process also transforms the sidewalls of the polysilicon layer 52 and the gate oxide layer 44 into the passivation layer 58, and the thickness of the passivation layer 58 is between 2 and 15 nanometers.

Since the sidewall of the conductive stack 50 is completely covered by the passivation layer 58, the sidewall of the tungsten layer 56 will not directly contact the hydrogen peroxide even while a subsequent cleaning process is performed using a cleaning solution including hydrogen peroxide to remove contaminant from the semiconductor substrate 42. Consequently, the present invention forms the passivation layer 58 on the sidewall of the conductive stack 50 to prevent the conductive stack 50 from being corroded by the oxidant in the cleaning solution to maintain the profile and the electrical properties of the gate structure 40. Optionally, after the annealing process is completed, a nitridation process can be performed in an atmosphere including ammonia gas (NH₃) at a temperature between 800° C. and 1100° C. to transform the silicon ions in the sidewall of the conductive stack 50 into silicon nitride (SiNₓ), i.e., the passivation layer 58 is made of silicon nitride. Further, after the annealing process is completed, an oxynitridation process can be performed in a nitrous oxide (N₂O) atmosphere at a temperature between 800° C. and 1100° C. to transform the silicon ions in the sidewall of the conductive stack 50 into silicon oxynitride (SiOₓN_{y}), i.e., the passivation layer 58 is made of silicon oxynitride.

Referring to FIG. 8, another implanting process is performed using the gate structure 10 as a mask to form diffusion regions 64 in the semiconductor substrate 42. Subsequently, the chemical vapor deposition process and the anisotropic etching process are used to form a spacer 60 on the sidewall of the gate structure 40. The spacer 60 can be made of silicon oxide, silicon nitride, or silicon oxynitride, and the cap layer 46 can be made of silicon nitride. Unlike the spacer 60 on the entire sidewall of the gate structure 10, the passivation layer 60 is formed only selectively on the sidewall of the conductive stack 50.

The prior art method exposes the tungsten layer of the gate structure to the oxidant in a cleaning solution, and the tungsten layer is corroded by the oxidant. On the contrary, the present gate structure includes a passivation layer on the sidewall of the conductive stack, and the passivation layer can protect the tungsten layer from exposure to the oxidant in the cleaning solution. Consequently, the present invention can prevent the conductive stack from being corroded by the oxidant to maintain the profile and the electrical properties of the gate structure.

The above-described embodiments of the present invention are intended to be illustrative only. Numerous alternative embodiments may be devised by those skilled in the art without departing from the scope of the following claims.

What is claimed is:

1. A gate structure, comprising:
a gate oxide layer positioned on a semiconductor substrate;
a conductive stack positioned on the gate oxide layer;
a cap layer positioned on the conductive stack; and
a passivation layer positioned on the sidewall of the conductive stack.

2. The gate structure of claim 1, wherein the conductive stack comprises:
a polysilicon layer positioned on the gate oxide layer;
a tungsten nitride layer positioned on the polysilicon layer;
a tungsten layer positioned on the tungsten nitride layer; and
a tungsten silicide layer positioned on the sidewall of the tungsten nitride layer and the tungsten layer.

3. The gate structure of claim 1, wherein the passivation layer is made of silicon oxide.

4. The gate structure of claim 1, wherein the passivation layer is made of silicon nitride.

5. The gate structure of claim 1, wherein the passivation layer is made of silicon oxynitride.

6. The gate structure of claim 1, wherein the thickness of the passivation layer is between 2 and 15 nanometers.

7. The gate structure of claim 1, further comprising a spacer positioned on the sidewall of the gate oxide layer, the conductive stack, and the cap layer.

8. The gate structure of claim 7, wherein the spacer is made of silicon oxide, silicon nitride, or silicon oxynitride.

9. The gate structure of claim 1, wherein the cap layer is made of silicon nitride.

10. A method for preparing a gate structure, comprising steps of:
forming a gate oxide layer on a semiconductor substrate;
forming a conductive stack on the gate oxide layer;
forming a cap layer on the conductive stack;
removing a predetermined portion of the gate oxide layer, the conductive stack, and the cap layer to form at least one opening;
implanting silicon ions into the sidewall of the conductive stack through the opening; and
forming a passivation layer on the sidewall of the conductive stack.

11. The method for preparing a gate structure of claim 10, wherein the step of forming a passivation on the sidewall of the conductive stack is performed by a thermal treating process to transform a predetermined portion of the sidewall implanted with silicon ions into the passivation layer.

12. The method for preparing a gate structure of claim 11, wherein the thermal treating process is a selective oxidation process performed in an atmosphere including hydrogen and steam, and the passivation is made of silicon oxide.

13. The method for preparing a gate structure of claim 12, wherein the selective oxidation process is performed at a temperature between 900° C. and 1200° C.

14. The method for preparing a gate structure of claim 11, further comprising a step of performing an annealing process to heat the semiconductor substrate including the conductive stack in an atmosphere including at least one inert gas up to a temperature above 800° C.

15. The method for preparing a gate structure of claim 14, wherein the thermal treating process is an oxidation process performed in an oxygen atmosphere, and the passivation layer is made of silicon oxide.

16. The method for preparing a gate structure of claim 15, wherein the thermal treating process is performed at a temperature between 900° C. and 1200° C.

17. The method for preparing a gate structure of claim 14, wherein the thermal treating process is a nitridation process performed in an atmosphere including ammonia gas, and the passivation layer is made of silicon nitride.

18. The method for preparing a gate structure of claim 17, wherein the thermal treating process is performed at a temperature between 800° C. and 1100°C.

19. The method for preparing a gate structure of claim 14, wherein the thermal treating process is an oxynitridation process performed in a nitrous oxide atmosphere, and the passivation layer is made of silicon oxynitride.

20. The method for preparing a gate structure of claim 19, wherein the thermal treating process is performed at a temperature between 800° C. and 1100° C.

21. The method for preparing a gate structure of claim 10, wherein the step of implanting silicon ions into the sidewall of the conductive stack through the opening is performed by a tilt implanting process.
